(19) United States
(12) Patent Application Publication
(10) Pub. No.: US 2005/0218939 A1
(43) Pub. Date: Oct. 6, 2005

(54) Under-voltage detection circuit

(76) Inventor: Fan Yung Ma, Singapore (SG)

Correspondence Address: SLATER & MATSIL LLP, 17950 PRESTON ROAD, SUITE 1000, DALLAS, TX, 75252, US

(21) Appl. No.: 10/519,867

(22) PCT Filed: Jul. 1, 2002
(86) PCT No.: PCT/SG02/00148

§ 371 Date: Dec. 30, 2004

(51) Int. Cl. H03K 5/153

(52) U.S. Cl. 327/78

(57) ABSTRACT

An-under-voltage detection (UVD) circuit includes a comparator 1 for determining the amount by which a voltage supply V_{supply} falls short of a reference voltage V_{ref}, and an integrator 3 for time-integrating this shortfall. In a glitch immunce operating mode of the UVD circuit, a reset is generated using this integrated value. A reset is only generated in the case that a glitch in the supply voltage V_{supply} has a duration longer than a critical duration. The critical duration depends upon the magnitude of the glitch and the component values of the integrator 3.

### FIELD OF THE INVENTION

The present invention relates to an under-voltage detection (UVD) circuit for a microprocessor, and to a microprocessor employing the UVD circuit.

### BACKGROUND OF THE INVENTION

Under-voltage detection (UVD) circuits are circuits for detecting when a supply voltage falls below a detection threshold. UVDs are used extensively in micro-controller based systems, and are used especially during power-up, power-down or brown-out conditions (i.e. supply conditions such that the supply voltage is generally below the detection threshold but includes some positive glitches). When the UVD senses that the value of a supply voltage is less than the detection threshold, it triggers a reset in the microprocessor by asserting a reset signal. In certain circumstances however (such as electrostatic discharge (ESD) tests) a short duration negative transient may occur which constitutes an under-voltage but which it may be preferable for the UVD circuit to ignore, so that a reset is not triggered.

It is believed that early microprocessor designs addressed this problem using an external capacitor connected near the supply pin to remove any supply glitches. Another way to achieve the same result would be to add an RC network within the microprocessor at the input of the voltage detection comparator. However, to provide a high level of glitch immunity requires large RC values, which is area intensive and therefore not suitable for IC implementation.

### SUMMARY OF THE INVENTION

The present invention seeks to provide a new and useful UVD circuit, and a microprocessor having such a circuit.

In general terms, the invention proposes that a UVD circuit integrates the difference between the supply voltage and a reference signal, and determines whether a reset should be generated using this integrated signal.

Specifically, the invention may be expressed as a UVD circuit for monitoring a supply voltage and which includes:
a comparator for generating a shortfall signal indicative of a shortfall of the supply voltage in relation to a reference voltage, and
an integrator for time-integrating the shortfall signal to form an integrated signal,
wherein the output of the integrator is used to generate a reset signal.

The integrated signal may itself constitute the reset signal which is transmitted directly to reset means for resetting the microprocessor. Alternatively, the integrated signal may be just a single input to a discriminator circuit which is arranged to generating the reset signal in dependence on (but not exclusively determined by) the integrated signal.

Preferably, the shortfall signal is a current signal having a value which increases with the shortfall of the supply voltage in relation to the reference voltage. In this case the integrator may be implemented straightforwardly as a analogue circuit including a capacitance. The comparator may optionally additionally generate a voltage signal indicative of the shortfall of the supply voltage in relation to the reference voltage, and this too may be used by the discriminator.

### BRIEF DESCRIPTION OF THE FIGURES

An embodiment of the invention will now be described in detail for the sake of example only, with reference to the following figures in which:

FIG. 1 is a schematic diagram of the UVD circuit of the embodiment;

FIG. 2 is a circuit diagram of the comparator of FIG. 1;

FIG. 3 is a circuit diagram of the embodiment;

FIG. 4 shows the current output of the comparator for a range of differences between the two input voltages;

FIG. 5, which is composed of FIGS. 5(a) and 5(b), shows the response of the embodiment to two different supply voltage profiles;

FIG. 6 shows the operation of the embodiment during slow power up and power down; and

FIG. 7 shows the minimum glitch duration required to trigger the embodiment in relation to the glitch magnitude.

### DETAILED DESCRIPTION OF THE EMBODIMENT

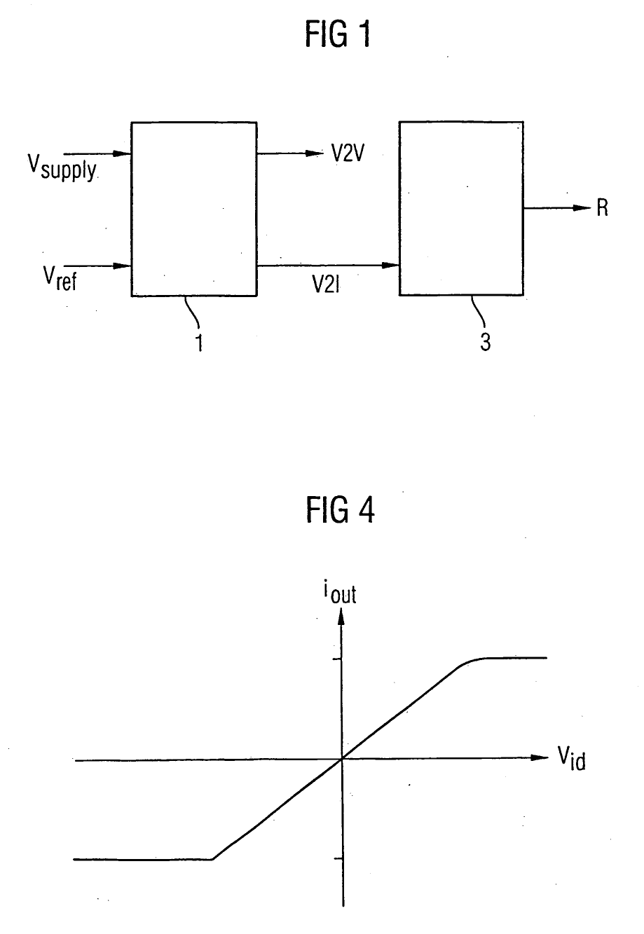

A schematic view of the embodiment is shown in FIG. 1. A comparator unit 1 receives two inputs: V_{supply}, which is the power supply voltage to be checked; and V_{ref} which is the reference voltage. It produces two outputs: V2V and V2I. V2I is a current which rises with (for example, may be proportional to) the shortfall of V_{supply} compared to V_{ref}. V2V is a voltage which rises with this shortfall (for example it may be proportional to V2I).

Of these, the output V2I is transmitted to an integrator unit 3, which integrates V2I and produces a reset signal, R.

Optionally R may be transmitted directly to reset means (which are not shown, but which may be of any conventional design) which reset the microprocessor/computer system. Alternatively, a discriminator (not shown) may be arranged to receive V2I (and optionally other inputs, such as control signals or V2V), and to generate a modified reset signal for transmission to the reset means.

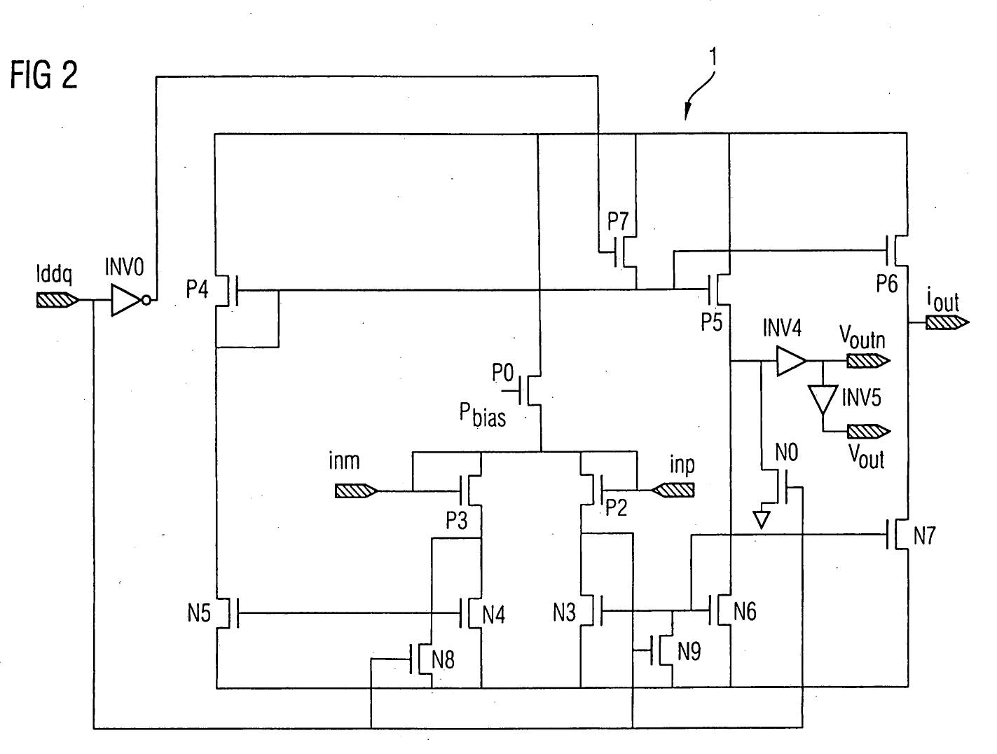

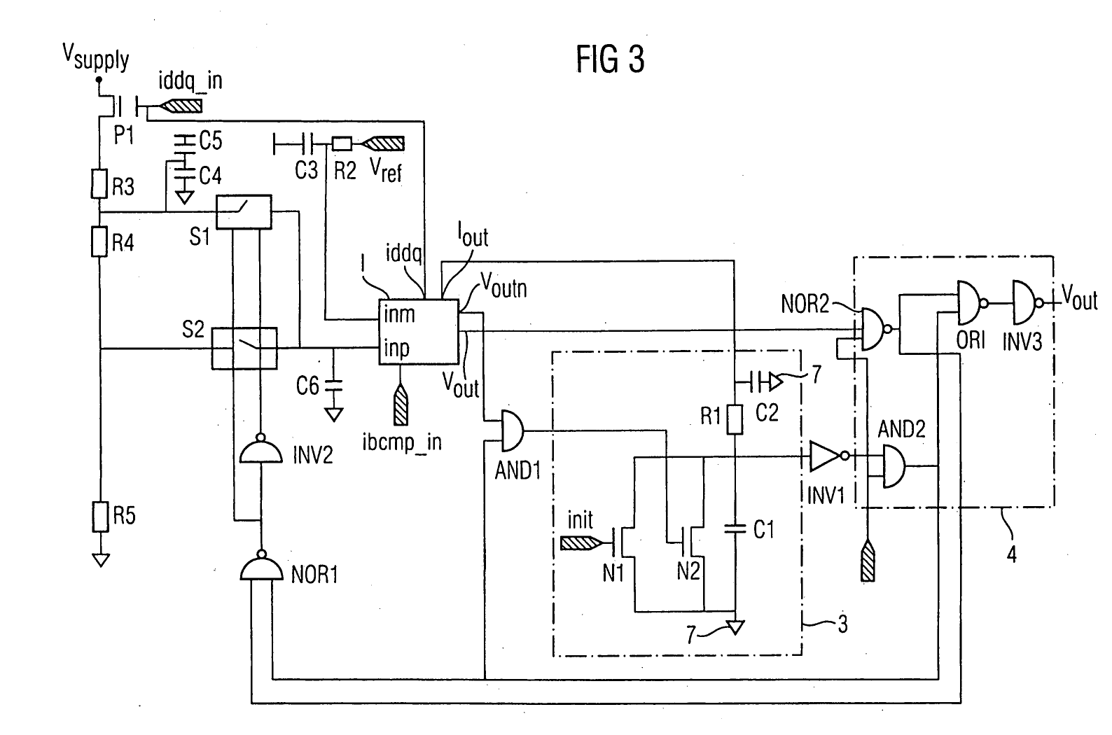

Detailed circuit diagrams of a possible comparator 1 and of its connection to the integrator 3 are given by FIGS. 2 and 3 respectively.

To begin with, we give an overview of FIG. 3. The comparator 1 receives two input voltage signals inm and inp which are respectively derived from a voltage reference signal V_{ref} and the voltage supply V_{supply}. The comparator generates a current output iₒᵤₜ and two voltage outputs Vₒᵤₜₙ and its inverse Vₒᵤₜₚ. As described below, iₒᵤₜ corresponds to V2I in FIG. 1, and is a current measure of the shortfall of inp in comparison to inm.

The current signal iₒᵤₜ is transmitted to the integrator 3, which produces an output signal Vₒ. A discriminator circuit 4 processes result Vₒ to generate a voltage which is a modified reset signal Rₒᵤₜ (a reset is triggered when this signal is low).

Referring now in more detail to FIG. 2, the comparator 1 is a transconductance amplifier circuit with current output iₒᵤₜ and voltage outputs Vₒᵤₜₙ and Vₒᵤₜₚ. The input differential pair is constituted by the transistors P2 and P3, which respectively receive the inputs inm and inp. This differential pair and the bias transistor P0 perform a voltage to current conversion to generate signal iₒᵤₜ.

It is well-known that, for V_{id}<\sqrt{2Iₛₛ/β} the difference of the drain currents of the transistor input devices P2, P3 can be described by the equation:
I_{dp3}−I_{dp2}=V_{id}\sqrt{βIₛₛ(1−βV_{id}²/4Iₛₛ)}
where V_{id}=inp-inm, Iₛₛ is the differential pair bias current (i.e. the current through transistor P0) and is a function of the device mobility, aspect ratio and gate oxide capacitance.

This equation is mirrored to the output, i.e. the comparator output iₒᵤₜ is governed by the same equation scaled by a gain factor determined by the gain factors of the transistors N4, N5, N3, P4, and P6. Therefore, according to the equation, iₒᵤₜ varies approximately linearly with V_{id} near V_{id}=0, and then saturates at higher positive and negative values of Iₛₛ. Therefore, prior to output current saturation this circuit approximates a linear voltage-to-current converter. The current-voltage profile is as shown in FIG. 4. The output is also used to generate a corresponding voltage output Vₒᵤₜ and its inverse Vₒᵤₜₙ.

Iddq is a power down signal which goes high to indicate that there will be a power down. Pbias is generated by a bias circuit (which is not shown in FIG. 3).

Turning back to FIG. 3, the integrator 3 is composed of a resistor R1 and two capacitors C1 and C2. It can be derived that for a unit step input applied at the input (from the iₒᵤₜ of the comparator), the output voltage Vₒ at the input of the inverter INV1 follows the equation:
Vₒ=k(t−τ(1−exp (−t/τ)) )u(t)
where
k=iₒᵤₜ/(C1+C2)
and
τ=R1*C1*C2/(C1+C2)
Also, exp is the natural logarithm exponential function, and u(t) is the unit step function. Basically, Vₒ has an approximately linear relationship with time. The integrator 3 thus performs an integration function, and the integrated voltage causes INV1 to change its state when its trip point is reached, thus generating a reset signal.

The discriminator 4 of FIG. 3 is controlled by an input signal en and permits both glitch immune (en=“1”) and glitch sensitive (en=“0”). In the glitch immune case, the AND gate AND2 transmits the output of the inverter INV1, this is transmitted through the OR gate OR1, and inverted by the inverter INV3. Thus, there is a low output (a modified reset signal which triggers a reset in the reset means) whenever the output of the integrator 3 is higher than the trip voltage V_{c} of the inverter INV1 and vice versa. In the glitch sensitive case, en is low and the output of the UVD circuit is determined instead by Vₒᵤₜ (since the output of the AND gate AND0 is always zero). Specifically, Rₒᵤₜ is high (low) when Vₒᵤₜ is high (low).

The configuration of the other components of FIG. 3 will be understood by a skilled reader. Transistor P1, resistors R3, R4 and R5, provide a scaled version of the supply voltage V_{supply}. Capacitors C4, C5 and C6, provide some limited fast glitch immunity using standard RC effects. To provide more glitch immunity using such techniques would however require large values of RC which is area intensive and not practical for IC implementation.

Resistor R2 and capacitor C3 provide a low-pass filter for the comparator reference signal to remove any effects of jitter in this signal.

Switches S1 and S2, together with gates NOR1 and INV2 are arranged to provide hysteresis in the detection. According to which of the switches S1 and S2 is turned on, the input inp is scaled. This means that the effective supply voltage seen by the comparator 1 can be higher or lower according to whether the reset has already been triggered.

Gate AND1 and transistor N2 are used to discharge C1 by connecting it to ground 7 once the input to INV1 decreases past the INV1 trip point. This is to prepare the circuit for the next positive event, e.g. power-up.

Transistor N1 and the input init are used to initialise the voltage across C1 to ground upon power-up. Normally, init is low, so that the transitor N1 is inactive, but upon an initialisation of the UVD circuit init is set to high, to ground C1.

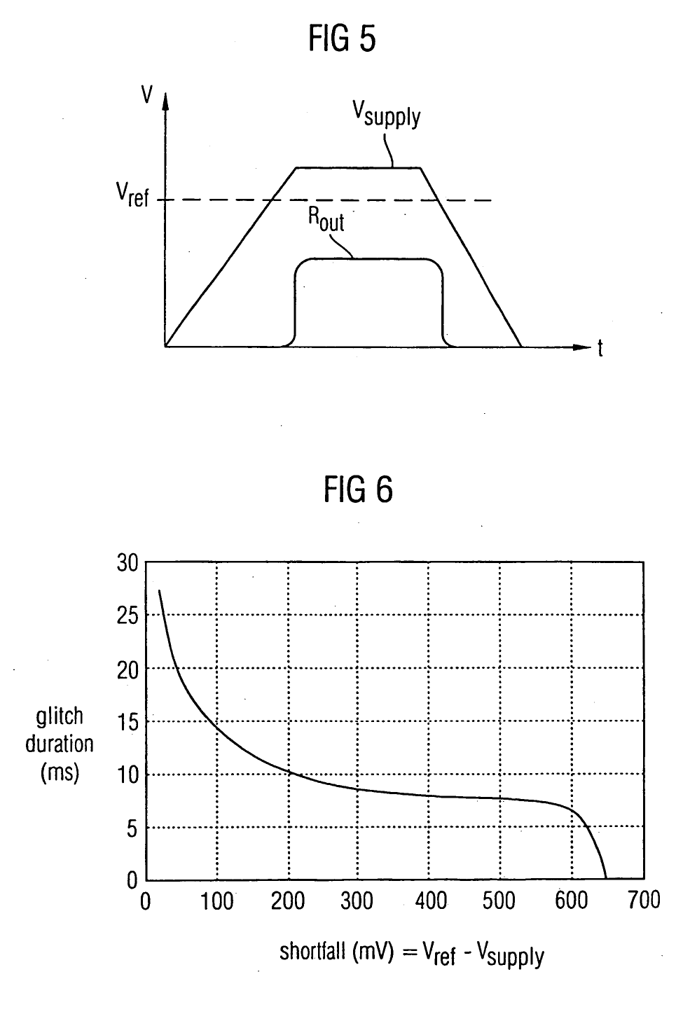

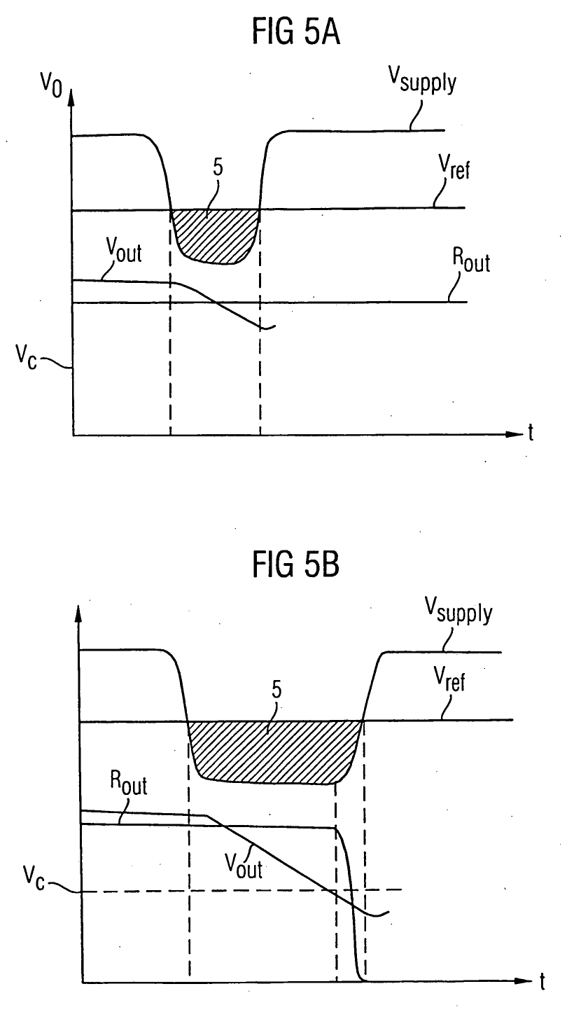

FIG. 5(a) shows schematically the time variation of the circuit in two cases, for both of which the UVD circuit is in the glitch immune state. In the case of FIG. 5(a) the supply voltage V_{supply} falls below V_{ref} for a short time indicated by the shaded area 5. Vₒ is high before this time, but during period 5 falls roughly in proportion to the time the glitch has lasted. However, Vsupply rises above Vref before the inverter INV1 is tripped, so the output Rₒᵤₜ remains at logic one, and there is no reset.

Conversely, in the case shown in FIG. 5(b), however, V_{supply} is below V_{ref} for sufficiently long that Vₒ falls below the trip voltage V_{c} of the inverter INV1, and Rₒᵤₜ falls to zero, i.e. there is a reset.

FIG. 6 shows the variation of Rₒᵤₜ with time during a slow power-up and power-down.

FIG. 7 shows, for typical component values in the circuits of FIGS. 2 and 3, the minimum duration of a glitch which will cause a reset for glitches of differing magnitudes (i.e. differing values of the shortfall of V_{supply} in relation to V_{ref}) in the glitch immune state of the UVD circuit. The magnitude of the glitches is given on the x-axis, while the time that such a glitch must last in order to cause a reset is shown on the y-axis. As can be seen from FIG. 7 a glitch of more than about 650 mV will cause a reset irrespective of its duration. For a wide range of glitch magnitudes (say 250 mV to 600 mV) a reset will only be caused if the duration of the glitch is more than about 7 μs.

Although only a single embodiment of the invention has been described in detail, various modifications are possible within the scope of the invention as will be clear to a skilled reader.

1. An under voltage detection (UVD) circuit for monitoring a supply voltage, the circuit comprising:
a comparator for generating a shortfall signal indicative of a shortfall of the supply voltage in relation to a reference voltage, and
an integrator for time-integrating the shortfall signal to form an integrated signal,
wherein the output of the integrator is used to generate a reset signal for resetting a microprocessor.

2. A UVD circuit according to claim 1 further including a discriminator circuit for receiving the integrated signal and at least one further output of the comparator, and generating a reset signal using the integrated signal and the at least one further output.

3. A UVD circuit according to claim 2 in which the discriminator circuit is arranged to receive a control signal, the discriminator circuit further comprising a switch controlled by the control signal for determining whether the reset signal is generated based on the integrated signal or the at least one further output signal.

4. A microprocessor comprising:
an under voltage detection (UVD) circuit that includes a comparator for generating a shortfall signal indicative of a shortfall of the supply voltage in relation to a reference voltage, and an integrator for time-integrating the shortfall signal to form an integrated signal, wherein the output of the integrator is used to generate a reset signal for resetting the microprocessor, and
reset means arranged to receive the reset signal output by the UVD circuit and according to its value to initiate a reset of the microprocessor.

5. A method of monitoring a supply voltage including:
generating a shortfall signal indicative of a shortfall of the supply voltage in relation to a reference voltage;
time-integrating the shortfall signal to form an integrated signal; and
generating a reset signal using the shortfall signal, wherein the reset signal is for resetting a microprocessor.

6. The method of claim 5 and further comprising resetting the microprocessor with the reset signal.

7. The microprocessor according to claim 4 wherein the UVD circuit further includes a discriminator circuit for receiving the integrated signal and at least one further output of the comparator, and generating a reset signal using the integrated signal and the at least one further output.

8. The microprocessor according to claim 7 in which the discriminator circuit is arranged to receive a control signal, the discriminator circuit further comprising a switch controlled by the control signal for determining whether the reset signal is generated based on the integrated signal or the at least one further output signal.
